(19) United States
(12) Patent Application Publication
(10) Pub. No.: US 2011/0278631 A1
(43) Pub. Date: Nov. 17, 2011

(54) LIGHT EMITTING DIODE CHIP

(75) Inventors: CHIA-HUI SHEN, Hukou Shiang (TW); TZU-CHIEN HUNG, Hukou Shiang (TW)

(73) Assignee: ADVANCED OPTOELECTRONIC TECHNOLOGY, INC., Hsinchu Hsien (TW)

(21) Appl. No.: 13/031,620

(22) Filed: Feb. 22, 2011

(30) Foreign Application Priority Data
May 13, 2010 (CN) 201010171388.3

(51) Int. Cl. H01L 33/38

(52) U.S. Cl. 257/99; 257/E33.066

(57) ABSTRACT

A light emitting diode (LED) chip includes a first electrode and a second electrode. Each of the first and second electrodes includes several trunks with at least one branch extending from at least one of the trunk, and at least one conductive pad serially connecting the trunks. A distance between a distal end of the branch of the first electrode and the conductive pad of the second electrode is less than that between any of other portions of the branch of the first electrode and the conductive pad of the second electrode, to thereby avoid crowded electric current formed at the first electrode and the conductive pad of the second electrode to save power accordingly.

### BACKGROUND

1. Technical Field

The present disclosure relates to a light emitting diode (LED), and particularly, to electrode arrangement of a light emitting diode chip of the LED.

2. Description of Related Art

A light emitting diode (LED) is semiconductor device, often including III-V Group chemical elements, such as gallium phosphide (GaP), gallium arsenide (GaAs), gallium nitride (GaN). When an LED is switched on, electrons recombine with electron holes within the device to release energy in the form of photons, creating electroluminescence with a color of the generated light determined by the energy gap of the semiconductor. The operation of the LED produces considerably less heat than, for example, a halogen lamp, such that the lifetime of an LED can exceed one hundred thousand hours. Additional advantages of fast response, small size, energy conservation, and minimal environmental impact, have resulted in widespread use of the LEDs in the lighting field.

An LED chip often includes a substrate, an N-type semiconductor layer located on the substrate, a P-type semiconductor layer located on the substrate, an N-type electrode adjacent to the N-type semiconductor layer, a P-type electrode adjacent to the P-type semiconductor layer, and an illumination layer located between the N-type semiconductor layer and the P-type semiconductor layer.

When voltage difference is applied to the N-type electrode and the P-type electrode of the LED chip, electrons and electron holes flow respectively from the N-type semiconductor layer and the P-type semiconductor layer into the illumination layer, and recombine therein to release energy in the form of photons.

FIG. 1 shows an N-type electrode 501 and a P-type electrode 502 of a related LED chip. The electrode 501 includes a spiral branch 505 and two conductive pads 503 connecting to the spiral branch 505; and the electrode 502 includes a spiral branch 506 and two conductive pads 504 connecting to the spiral branch 506. The spiral branch 505 defines two turning portions 507 corresponding to the two conductive pads 504; and the spiral branch 506 defines two turning portions 508 corresponding to the two conductive pads 503.

Since the turning portions 507 and 508 of the electrodes 501 and 502 are located respectively near the conductive pads 503 and 504 of the electrodes 502 and 501, current is easily bottlenecked at the turning portions 507 and 508 and the conductive pads 503 and 504, such that current density is not uniform in the LED chip, voltage difference between the two electrodes 501 and 502 is increased, and power consumption in the LED chip increases.

Accordingly, it is desirable to provide an LED chip which can overcome the described limitations.

### BRIEF DESCRIPTION OF THE DRAWINGS

Many aspects of the disclosure can be better understood with reference to the drawings. The components in the drawings are not necessarily drawn to scale, the emphasis instead being placed upon clearly illustrating the principles of the present disclosure. Moreover, in the drawings, like reference numerals designate corresponding parts throughout the views.

FIG. 1 is a schematic view of electrode arrangement of a commonly used LED chip.

FIG. 2 is a schematic view of electrode arrangement of an LED chip according to a first embodiment of the present disclosure.

FIG. 3 is a schematic view of electrode arrangement of an LED chip according to a second embodiment of the present disclosure.

FIG. 4 is a schematic view of electrode arrangement of an LED chip according to a third embodiment of the present disclosure.

### DETAILED DESCRIPTION

Embodiments of the disclosure are now described in detail with reference to the accompanying drawings.

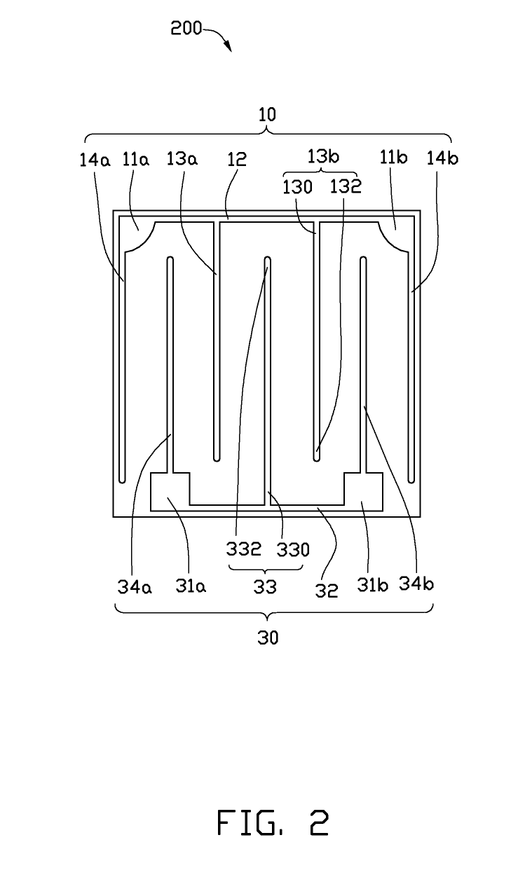

FIG. 2 illustrates an electrode structure 200 of an LED chip according to a first embodiment. As shown in FIG. 2, the electrode structure 200 includes a first electrode 10 (i.e., N-type electrode) and a second electrode 30 (i.e., P-type electrode) for receiving a driving power for the LED chip. The LED chip is substantially a rectangle in top view, and the first electrode 10 and the second electrode 30 form a cross-finger pattern.

The first electrode 10 includes two first conductive pads 11a and 11b located at two adjacent corners of the LED chip, a first horizontal trunk 12 interconnecting the first conductive pads 11a and 11b, two first vertical trunks 14a and 14b respectively extending from the first conductive pads 11a and 11b, and two first vertical branches 13a and 13b extending from the middle portion of the first horizontal trunk 12. The first conductive pad 11a and 11b serially connect the first trunks 12, 14a and 14b. Each of the first horizontal trunk 12, the first vertical trunks 14a, 14b, and the first vertical branches 13a and 13b is substantially a strip. In the present disclosure, the difference between trunks and branches is that the trunks extend from the conductive pads, and the branches extend from the trunks.

The first horizontal trunk 12 and the two first vertical trunks 14a and 14b are arranged as three sides of a rectangle. The first horizontal trunk 12 is perpendicular to the two first vertical trunks 14a and 14b. The first vertical branches 13a and 13b are parallel to the first vertical trunks 14a and 14b, and perpendicular to the first horizontal trunk 12. A distance between the two first vertical branches 13a and 13b, a distance between the first vertical branch 13a and the first vertical trunk 14a, and a distance between the first vertical branch 13b and the first vertical trunk 14b are substantially the same.

Each of the first vertical branches 13a and 13b includes a terminal 130 connected to the middle portion of the first horizontal trunk 12, and a distal end 132 opposite to the terminal 130. Each of the first conductive pads 11a and 11b has a shape of a quarter circle. The first conductive pads 11a and 11b are respectively located at two terminals of the first horizontal trunk 12, and also the intersections of the corresponding first vertical trunks 14a and 14b and the first horizontal trunk 12.

The second electrode 30 includes two second conductive pads 31a and 31b, a second horizontal trunk 32 interconnecting the second conductive pads 31a, 31b, two second vertical trunks 34a and 34b respectively extending from the second conductive pads 31a and 31b, and a second vertical branch 33 extending from the middle portion of the second horizontal trunk 32. The second conductive pad 31a and 31b serially connect the second trunks 32, 34a and 34b. Each of the second horizontal trunk 32, the second vertical trunks 34a, 34b, and the second vertical branch 33 is substantially a strip.

The second horizontal trunk 32 and the two second vertical trunks 34a and 34b are arranged as three edges of a rectangle. The second horizontal trunk 32 is perpendicular to the two second vertical trunks 34a and 34b. The second vertical branch 33 is parallel to the second vertical trunks 34a and 34b, and perpendicular to the second horizontal trunk 32. A distance between the second vertical branch 33 and the second vertical trunk 34a, and a distance between the second vertical branch 33 and the second vertical trunk 34b are substantially the same.

The second vertical branch 33 includes a terminal 330 connected to the middle portion of the second horizontal trunk 32, and a distal end 332 opposite to the terminal 330. Each of the second conductive pads 31a and 31b is rectangular. The second conductive pads 31a and 31b are respectively located at two terminals of the second horizontal trunk 32, and also the intersections of the corresponding second vertical trunks 34a and 34b and the second horizontal trunk 32.

The two first vertical trunks 14a and 14b, the first horizontal trunk 12 and the second horizontal trunk 32 respectively correspond to four edges of the LED chip, as seen in the top view. The electrode structure 200 is reflectively symmetric relative to an extension line of the second vertical branch 33, which may be a central line of the LED chip. The first horizontal trunk 12 is parallel to and apart from the second horizontal trunk 32. Each of the first vertical branches 13a and 13b vertically extends from the first horizontal trunk 12 toward the second horizontal trunk 32 of the second electrode 30. The second vertical branch 33 is located between the two first vertical branches 13a and 13b. The first vertical trunks 14a and 14b, the second vertical trunks 34a and 34b, the first vertical branches 13a and 13b and the second vertical branch 33 are parallel to each other.

The first vertical trunks 14a, 14b, the first vertical branches 13a, 13b of the first electrode 10 and the second vertical trunks 34a, 34b, the second vertical branch 33 of the second electrode 30 are alternately arranged and equidistantly spaced to form the cross-finger pattern. Each of the distal ends 132 of the first vertical branches 13a and 13b is located near the second horizontal trunk 32 but has a distance from the second horizontal trunk 32. The distal end 332 of the second vertical branch 33 is located near the first horizontal trunk 12 but has a distance from the first horizontal trunk 12. A distance between the two first conductive pads 11a and 11b exceeds that between the two second conductive pads 31a and 31b.

It is noted that a distance between each of the distal ends 132 and each of the second conductive pads 31a, 31b is less than a distance between any other portion of each of the first vertical branches 13a, 13b and each of the second conductive pads 31a, 31b. A distance between the distal end 332 and each of the first conductive pads 11a, 11b is less than a distance between any other portion of the second vertical branch 33 and each of the first conductive pads 11a, 11b. The distance between each of the distal ends 132 and a neighboring second conductive pad 31a (31b) is a minimum distance between the first and second electrodes 10, 30.

When the LED chip is switched on, a voltage difference is applied to the first electrode 10 and the second electrode 30. The current flows into the LED chip through the first conductive pads 11a and 11b and toward a P/N interface (not shown). Electrons are able to recombine with electron holes within the LED chip to release energy in the form of photons. The current thereafter convergences to the second electrode 30 through different pathways between the first electrode 10 and the second electrode 30, and flows out of the LED chip through the second conductive pads 31a and 31b of the second electrode 30.

Since each of the first horizontal trunk 12, the first vertical trunks 14a, 14b, the first vertical branches 13a, 13b, the second horizontal trunk 32, the second vertical trunks 34a, 34b, and the second vertical branch 33 is a strip, and the first electrode 10 and the second electrode 30 have the cross-finger pattern, the LED chip can have uniform current density therein.

Since the distal ends 132 and 332 are the nearest portions between the branches 13a, 13b, 33 and the conductive pads 31a, 31b, 11a, 11b, the present disclosure prevents crowded electric currents at turning portions or the conductive pads 11a, 11b, 31a, 31b. Thus, the voltage difference between the first electrode 10 and the second electrodes 30 can be reduced, and thereby more power can be saved.

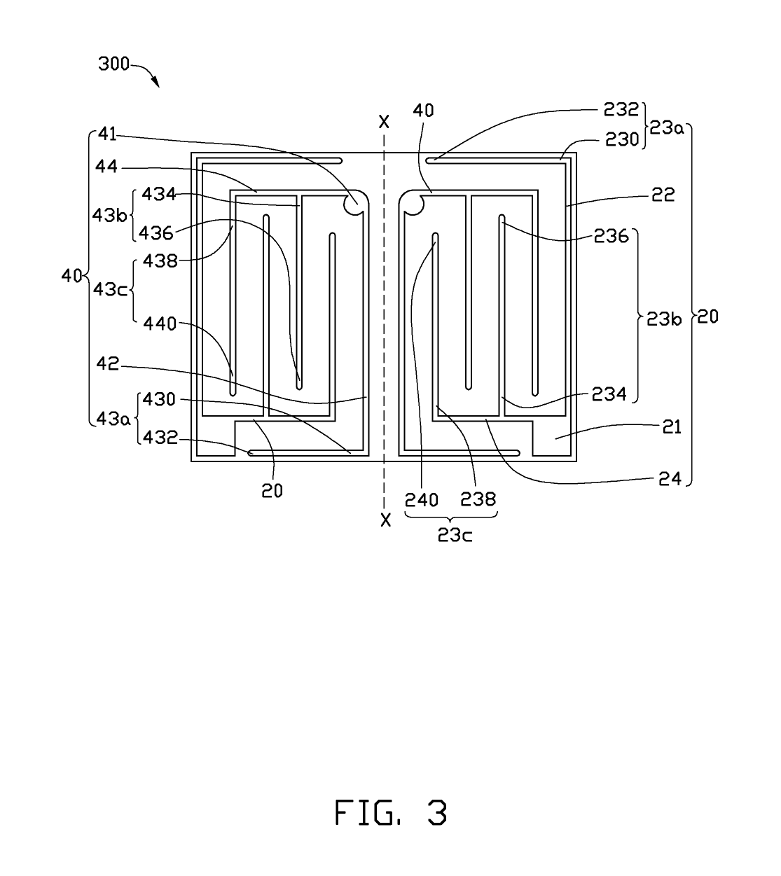

The present disclosure provides electrode structure of LED chips to avoid crowded electric current formed at the first electrode and the second electrode. Within this spirit, the electrode structures of the present disclosure can be adjusted. FIG. 3 illustrates an electrode structure 300 of an LED chip according to a second embodiment. The differences between the electrode structure 300 and the electrode structure 200 are that the electrode structure 300 includes two electrode pairs each including a first electrode 40 and a second electrode 20; each of the second and first electrodes 20 and 40 only includes one conductive pad 21 or 41; and the second and first electrodes 20 and 40 further include second horizontal branch 23a and first horizontal branch 43a respectively.

The electrode structure 300 includes the two electrode pairs reflectively symmetric relative to a central line X-X of the LED chip. The first electrode 40 further comprises a first horizontal trunk 44, a first vertical trunk 42, a first horizontal branch 43a and two first vertical branches 43b, 43c. Since the first electrode 40 only includes one first conductive pad 41, the first vertical branch 43c now functions as a branch rather than a trunk. In this embodiment, the first conductive pad 41 has a shape of a circle. The first vertical trunk 42 extends from the first horizontal branch 43a to reach the first conductive pad 41. The first horizontal trunk 44 extends from the first conductive pad 41. The first vertical branches 43b, 43c extend from the first horizontal trunk 44.

The second electrode 20 further comprises a second horizontal trunk 24, a second vertical trunk 22, a second horizontal branch 23a and two second vertical branches 23b, 23c. Since the second electrode 20 only includes one second conductive pad 21, the second vertical branch 23c now functions as a branch rather than a trunk. In this embodiment, the second conductive pad 21 has a shape of a rectangle. The second vertical trunk 22 extends from the first horizontal branch 23a to reach the second conductive pad 21. The first horizontal trunk 24 extends from the first conductive pad 21. The first vertical branches 23b, 23c extend from the first horizontal trunk 24.

The first horizontal branch 43a, the first vertical branch 43b, the first vertical branch 43c, the second horizontal branch 23a, the second vertical branch 23b and the second vertical branch 23c are respectively includes terminals 430, 434, 438, 230, 234, 238 and distal ends 432, 436, 440, 232, 236, 240 opposite to the terminals 430, 434, 438, 230, 234, 238. The first horizontal branch 43a, the second vertical trunk 22 and the second horizontal branch 23a respectively correspond to the three edges of the LED chip in top view, and the first vertical trunk 42 corresponds to the central line X-X of the LED chip.

The second vertical trunk 22 and the second vertical branches 23b, 23c of the second electrode 20 are alternate with the first vertical trunk 42 and the first vertical branches 43b, 43c of the first electrode 40 and equidistantly spaced therefrom.

Moreover, it is noted that a distance between the first conductive pad 41 and each of the distal ends 232, 236, 240 is less than a distance between the first conductive pad 41 and any other portion of each of the second horizontal branch 23a and the second vertical branches 23b, 23c. A distance between the second conductive pad 21 and each of the distal ends 432, 436, 440 is less than a distance between the second conductive pad 21 and any other portion of each of the first horizontal branch 43a and the first vertical branches 43b, 43c. Thus, a uniform current density can be distributed over the LED chip when a power is applied between the first and second electrodes 40, 20.

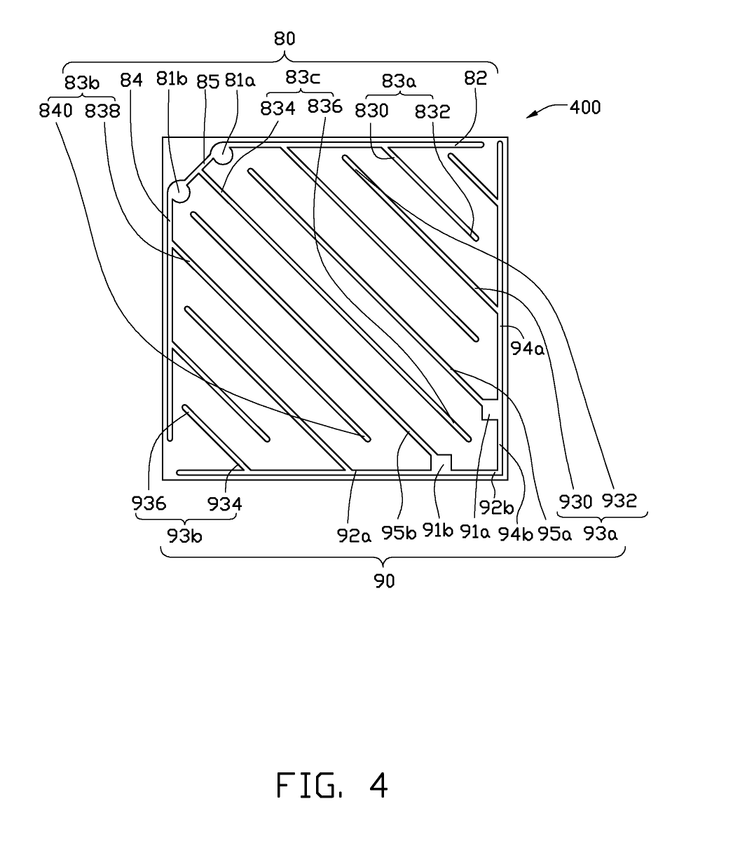

FIG. 4 illustrates an electrode structure 400 of an LED chip according to a third embodiment. The differences between the electrode structures 400 and 200 are that the branches 83a, 83b, 83c, 93a and 93b and the trunks 85, 95a and 95b are angled; the electrode structure 400 is symmetric relative to a diagonal line of the LED chip coincidental with the branch 83c. The branches 83a, 83b, 93a and 93b extend from horizontal and vertical trunks 92a, 92b, 94a, 94b, 82 and 84 of the first and second electrode 80, 90.

The first electrode 80 includes the first horizontal trunk 82, the first vertical trunk 84 and the first angled trunk 85, and two first conductive pads 81a and 81b located on two terminals of the first angled trunk 85 to connect the first horizontal trunk 82 and the first vertical trunk 84, and the five first angled branches 83a, 83b, 83c parallel to each other. The angled branch 83c substantially aligns the diagonal line of the LED chip, but is not limited thereto.

The second electrode 90 includes two second conductive pads 91a and 91b, the two second horizontal trunks 92a and 92b connecting to each other through the second conductive pad 91b, the two second vertical trunks 94a and 94b connecting to each other through the second conductive pad 91a, four second angled branches 93a and 93b parallel to each other, and two second angled trunks 95a and 95b respectively extending from the two second conductive pads 91a and 91b. The second horizontal trunk 92b is connected to the second vertical trunk 94b at a right, lower corner of the LED chip of FIG. 4. Each of the first conductive pads 81a and 81b has a shape of a circle, and each of the second conductive pads 91a, 91b has a shape of a rectangle.

The first horizontal trunk 82, the first vertical trunk 84, the second horizontal trunks 92a and 92b, the second vertical trunks 94a and 94b respectively correspond to the four edges of the LED chip in top view. The angled branches 83a, 83b, 83c of the first electrode 80 are alternate with the angled branches 93a and 93b and the angled trunks 95a and 95b of the second electrode 90, equidistantly spaced from each other and parallel to each other. The first horizontal trunk 82 and the angled branches 83a, 83b, 83c, 93a, 93b and the angled trunks 95a, 95b may be directed along the diagonal line, but not limited thereto. For example, an angle between the first horizontal trunk 82 and the angled branches 83a, 83b, 83c, 93a, 93b or the angled trunks 95a, 95b can be any acute angle.

The first angled branches 83a, 83b, 83c and the second angled branches 93a and 93b respectively include terminals 830, 838, 834, 930, 934 and distal ends 832, 840, 836, 932, 936 opposite to the terminals 830, 838, 834, 930, 934.

It is noted that a distance between each of the distal ends 832, 840, 836 and each of the second conductive pads 91a, 91b is less than a distance between any other portion of each of the first angled branches 83a, 83b, 83c and each of the second conductive pads 91a or 91b. A distance between each of the distal ends 930, 934 and each of the first conductive pads 81a, 81b is less than a distance between any other portion of each of the second angled branches 93a, 93b and each of the first conductive pads 81a, 81b.

The numbers, shapes and arrangements of the conductive pads, trunks and branches are not limited to the above embodiments, and can be adjusted as required.

Some advantages of the present disclosure can be seen in Table 1, which shows experiment data of voltage differences of electrode structures 200, 300, 400 of the LED chips in the present disclosure and the related electrode structure. In the experiments, the same currents are applied to each electrode structure.

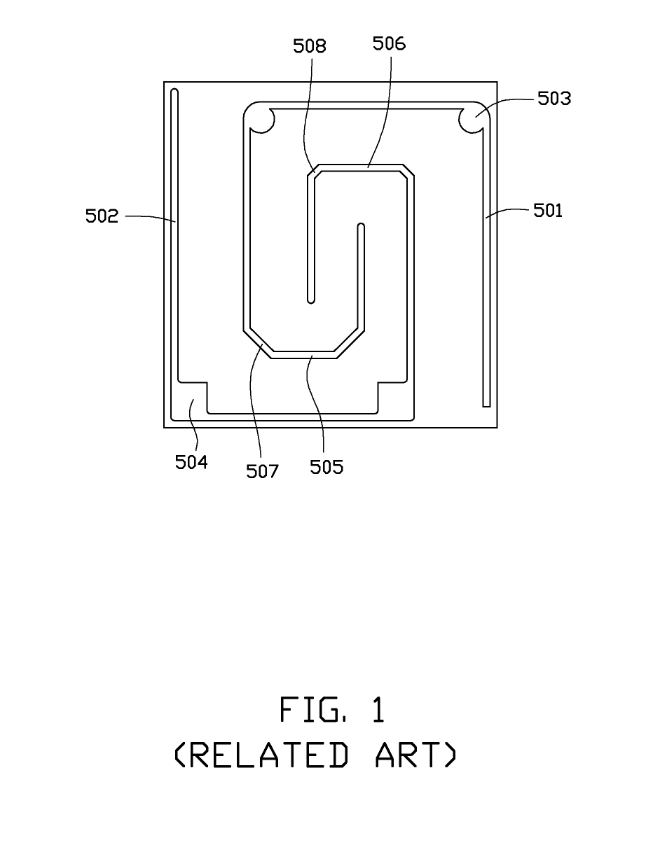

TABLE 1
Voltage differences of electrode structures of the LED chips

| Electrode structure of the LED chip | Voltage difference (volt) |
|---|---|
| the electrode structure of the first | 4.258 |
| embodiment in FIG. 2 | |
| the electrode structure of the second | 4.187 |
| embodiment in FIG. 3 | |
| the electrode structure of the third | 4.172 |
| embodiment in FIG. 4 | |
| the related electrode structure in FIG. 1 | 4.359 |

As shown in Table 1, voltage differences between the first electrode and second electrode of the present disclosure are less than that of the related electrode structure. Since the distance between the distal end of a branch of one electrode and the conductive pad of another electrode is less than that between any other portion of the branch and the conductive pad, the present disclosure prevents crowded electric currents at turning portions or the conductive pads. Furthermore, current densities of distal ends are properly compensated. Thus, the voltage difference between the electrodes can be reduced, and the power saved.

It is to be understood, however, that even though numerous characteristics and advantages of the present embodiments have been set fourth in the foregoing description, together with details of the structures and functions of the embodiments, the disclosure is illustrative only, and changes may be made in details, especially in matters of shape, size, and arrangement of parts within the principles of the disclosure to the full extent indicated by the broad general meaning of the terms in which the appended claims are expressed.

What is claimed is:

1. An electrode structure of a light emitting diode (LED) chip, comprising a first electrode pair, the first electrode pair comprising:
a first electrode, comprising:
a plurality of first trunks;
at least one first conductive pad serially connecting the plurality of first trunks; and
at least one first branch extending from the plurality of first trunks, the at least one first branch comprising a distal end far from the plurality of first trunks; and
a second electrode, comprising:
a plurality of second trunks;
at least one second conductive pad serially connecting the plurality of second trunks; and
at least one second branch extending from the plurality of second trunks;
wherein a distance between the distal end of the at least one first branch and the at least one second conductive pad is less than a distance between any other portion of the at least one first branch and the at least one second conductive pad.

2. The electrode structure of claim 1, wherein the distance between the distal end of the at least one first branch and the at least one second conductive pad is a minimum distance between the first electrode and the second electrode.

3. The electrode structure of claim 1, wherein each of the plurality of first trunks, each of the plurality of second trunks, the at least one first branch, and the at least one second branch are all substantially a strip.

4. The electrode structure of claim 3, wherein the plurality of first trunks comprise a first horizontal trunk and two first vertical trunks, the plurality of second trunks comprise a second horizontal trunk and two second vertical trunks, and the first electrode and the second electrode form a cross-finger pattern.

5. The electrode structure of claim 4, wherein the plurality of first trunks are arranged as three edges of a first rectangle, and the plurality of second trunks are arranged as three edges of a second rectangle.

6. The electrode structure of claim 5, wherein the at least one first conductive pad comprises two first conductive pads located on two terminals of the first horizontal trunk to connect the two first vertical trunks; and the at least one second conductive pad comprises two second conductive pads located on two terminals of the second horizontal trunk to connect the two second vertical trunks.

7. The electrode structure of claim 6, wherein a distance between the two first conductive pads exceeds a distance between the two second conductive pads.

8. The electrode structure of claim 6, wherein the at least one first branch comprises two first vertical branches extending from the first horizontal trunk and parallel to the two first vertical trunks.

9. The electrode structure of claim 8, wherein the at least one second branch extends from the second horizontal trunk and parallel to the two second vertical trunks.

10. The electrode structure of claim 9, wherein the at least one second branch is parallel to the two first vertical branches and located between the two first vertical branches.

11. The electrode structure of claim 1, wherein the at least one first conductive pad has a shape of a quarter circle, and the at least one second conductive pad is rectangular.

12. The electrode structure of claim 3, further comprising a second electrode pair, wherein the second electrode pair and the first electrode pair are reflectively symmetric relative to a central line of the LED chip.

13. The electrode structure of claim 12, wherein the plurality of first trunks comprise a first vertical trunk and a first horizontal trunk, and the plurality of second trunks comprise a second vertical trunk and a second horizontal trunk.

14. The electrode structure of claim 13, wherein the at least one first branch comprises two first vertical branches extending from the first horizontal trunk and a first horizontal branch extending from the first vertical trunk.

15. The electrode structure of claim 14, wherein one of the two first vertical branches extends from a terminal of the first horizontal trunk, and the first horizontal branch extends from a terminal of the first vertical trunk.

16. The electrode structure of claim 3, wherein the plurality of first trunks comprise a first horizontal trunk, a first vertical trunk and an angled first trunk, and the at least one first conductive pad comprises two first conductive pads located on two terminals of the angled first trunk to connect the first horizontal trunk and the first vertical trunk.

17. The electrode structure of claim 16, wherein the at least one second conductive pad comprises two second conductive pads,

18. The electrode structure of claim 17, wherein the plurality of second trunks comprise:
two second horizontal trunks connecting to each other through one of the two second conductive pads;
two second vertical trunks connecting to each other through another one of the two second conductive pads, and one of the two second horizontal trunks connecting to one of the two second vertical trunks; and
two second angled trunks respectively extending from the two second conductive pads.

19. The electrode structure of claim 18, wherein the at least one first branch and the at least one second branch comprise a plurality of angled branches parallel to each other, and an angle between the first horizontal trunk and the plurality of angled branches is acute.
